(19) United States
(12) Patent Application Publication
(10) Pub. No.: US 2026/0221391 A1
(43) Pub. Date: Jul. 30, 2026

(54) SUBSTRATE PROCESSING APPARATUS AND SUBSTRATE PROCESSING METHOD

(71) Applicant: Tokyo Electron Limited, Tokyo (JP)

(72) Inventors: Eiichi KOMORI, Yamanashi (JP); Eito OGURA, Yamanashi (JP)

(21) Appl. No.: 19/355,326

(22) Filed: Oct. 10, 2025

(30) Foreign Application Priority Data
Oct. 24, 2024 (JP) 2024-187632

(51) Int. Cl. H01J 37/32

(52) U.S. Cl. CPC H01J 37/32449; H01J 37/32091; H01J 37/32715; H01J 37/32733; H01J 37/32834; H01J 2237/1825; H01J 2237/186; H01J 2237/2007

(57) ABSTRACT

Substrate processing apparatus includes: processing chamber; mounting table situated in processing chamber and on which substrate is mounted; gas supply mechanism facing mounting table and supplying processing gas to substrate; processing region formed between mounting table and gas supply mechanism; gas exhaust region via which gas is exhausted by gas exhaust part; first gas exhaust path that is formed in gap between mounting table and gas supply mechanism and through which processing gas flows from processing region to gas exhaust region; second gas exhaust path provided in gas supply mechanism and connecting processing region to gas exhaust region such that processing gas can flow; third gas exhaust path through which processing gas is exhausted from gas exhaust region; and controller. Controller adjusts substrate processing condition based on gap between mounting table and gas supply mechanism, supply conditions of processing gas supplied from gas supply mechanism, and pressure in processing chamber.

### CROSS-REFERENCE TO RELATED APPLICATION

The present application claims priority under 35 U.S.C. § 119 to Japanese Patent Application No. 2024-187632, filed Oct. 24, 2024, the contents of which are incorporated herein by reference in their entireties.

### BACKGROUND OF THE INVENTION

### Field of the Invention

The present disclosure relates to a substrate processing apparatus and a substrate processing method.

### Description of the Related Art

Japanese Patent Application Laid-Open Publication No. 2009-224775 discloses a semiconductor manufacturing apparatus in which a diffusion space is formed between a mounting table configured to be moved up and down and a recess in a top plate member, to subject a substrate to a film forming process by an ALD process by supplying a processing gas into the diffusion space.

### SUMMARY OF THE INVENTION

According to one embodiment, a substrate processing apparatus is provided, which includes: a processing chamber; a mounting table that is situated in the processing chamber and on which a substrate is mounted; a gas supply mechanism situated so as to face the mounting table and configured to supply a processing gas to the substrate; a processing region formed between the mounting table and the gas supply mechanism; a gas exhaust region via which a gas is exhausted by a gas exhaust part; a first gas exhaust path that is formed in a gap between the mounting table and the gas supply mechanism and through which the processing gas flows from the processing region to the gas exhaust region; a second gas exhaust path provided in the gas supply mechanism and connecting the processing region to the gas exhaust region such that the processing gas can flow from the processing region to the gas exhaust region; a third gas exhaust path through which the processing gas is exhausted from the gas exhaust region; and a controller, wherein the controller is configured to adjust a processing condition of the substrate based on the gap between the mounting table and the gas supply mechanism, a supply condition of the processing gas supplied from the gas supply mechanism, and a pressure in the processing chamber.

### BRIEF DESCRIPTION OF THE DRAWINGS

FIG. 1 is an example of a schematic view showing an example configuration of a substrate processing apparatus;

FIG. 2 is an example of a bottom view of a showerhead;

FIG. 3A is an example of a view explaining a gas flow;

FIG. 3B is an example of a view explaining a gas flow;

FIG. 4 is an example of a flowchart illustrating a substrate processing method;

FIG. 5 is an example of a diagram showing a recipe of a substrate processing method; and

FIG. 6 is a graph illustrating an example of pressure change.

### DETAILED DESCRIPTION OF THE DISCLOSURE

An embodiment for carrying out the present disclosure will be described below with reference to the drawings. In each of the drawings, the same components are denoted by the same reference numerals, and duplicate descriptions may be omitted.

### Substrate Processing Apparatus

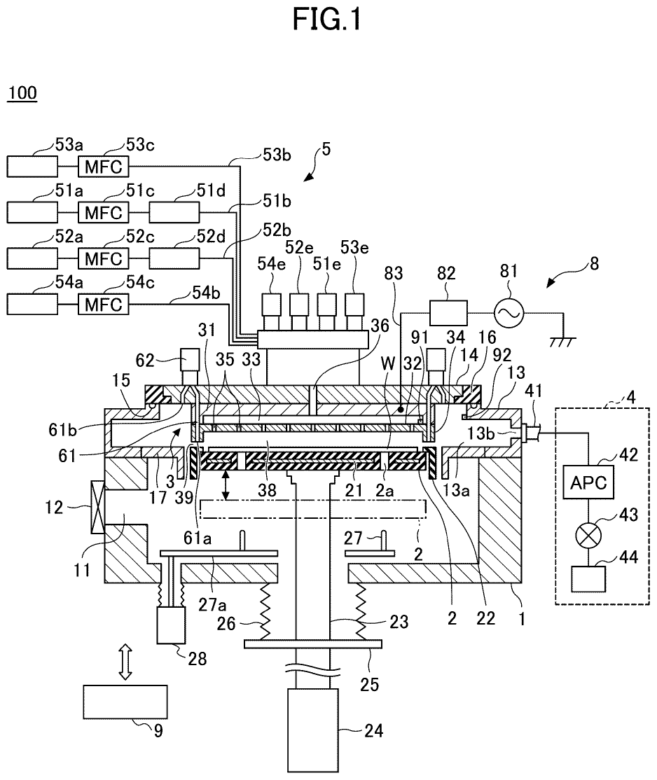

The substrate processing apparatus 100 according to the present embodiment will be described with reference to FIG. 1. FIG. 1 is a schematic diagram showing an example of the configuration of the substrate processing apparatus 100. The substrate processing apparatus 100 is an apparatus for forming a desired film on a substrate W, such as a wafer and the like, by an Atomic Layer Deposition (ALD) process in a processing vessel 1 that is at a reduced pressure. In the following description, an example case of forming a TiN film on a substrate W by the ALD process will be described.

As shown in FIG. 1, the substrate processing apparatus 100 includes the processing vessel (processing chamber) 1, a mounting table 2, a showerhead (gas supply mechanism) 3, a gas exhaust part 4, a gas supply part 5, an RF power supply 8, and a controller 9.

The processing vessel 1 is composed of a metal, such as aluminum and the like, and has a substantially cylindrical shape. The processing vessel 1 houses the substrate W. A loading/unloading opening 11 for loading or unloading the substrate W is formed in the side wall of the processing vessel 1, and the loading/unloading opening 11 is opened and closed by a gate valve 12. An annular gas exhaust duct 13 having a rectangular cross-sectional shape is provided on the body of the processing vessel 1. An approximately annular gas exhaust space (gas exhaust region) 13a is formed in the gas exhaust duct 13. A gas exhaust opening 13b is formed in the outer wall of the gas exhaust duct 13. A top wall 14 is provided on the upper surface of the gas exhaust duct 13 so as to close the upper opening of the processing vessel 1 via an insulator member 16. The gap between the gas exhaust duct 13 and the insulator member 16 is airtightly sealed by a seal ring 15. When the mounting table 2 (and a cover member 22) is moved upward to the processing position, which is described later, a partitioning member 17 partitions the interior of the processing vessel 1 in the vertical direction to form an upper space and a lower space. In the upper space of the processing vessel 1, a space that is on the radially outer side of a processing space 38 and an annular clearance 39 described later is the gas exhaust space 13a. In the upper space of the processing vessel 1, a space that is on the radially inner side of the annular clearance 39 described later is the processing space 38.

The mounting table 2 horizontally supports the substrate W in the processing vessel 1. The mounting table 2 is formed in the shape of a disk having a size corresponding to the substrate W and is supported by a support member 23. The mounting table 2 is composed of a ceramic material, such as AlN and the like, or a metal material, such as aluminum, a nickel alloy, and the like, and a heater 21 for heating the substrate W is embedded therein. The heater 21 generates heat by being supplied with power from a heater power source (not shown). The substrate W is controlled to a predetermined temperature by the output power of the heater 21 being controlled based on a temperature signal of a thermocouple (not shown) provided near the upper surface of the mounting table 2. The cover member 22 composed of a ceramic, such as alumina and the like, is provided on the mounting table 2 so as to cover the outer peripheral region of the upper surface of the mounting table 2 and the side surface of the mounting table 2.

The support member 23 for supporting the mounting table 2 is provided on the bottom surface of the mounting table 2. The support member 23 extends from the center of the bottom surface of the mounting table 2 to under the processing vessel 1 through a hole formed in the bottom wall of the processing vessel 1, and the lower end of the support member 23 is connected to a lifting mechanism 24. Via the support member 23, the lifting mechanism 24 moves the mounting table 2 up and down between a processing position indicated by the solid lines in FIG. 1 and a lower conveying position, indicated by dash-dotted lines, at which the substrate W can be conveyed. A flange 25 is attached to a part of the support member 23 that is under the processing vessel 1, and a bellows 26 that partitions the atmosphere in the processing vessel 1 from the open air and extends and contracts along with the operation of moving up and down the mounting table 2 is provided between the bottom surface of the processing vessel 1 and the flange 25.

Three (only two are shown) substrate support pins 27 are provided near the bottom surface of the processing vessel 1 so as to project upward from a lifting plate 27a. A lifting mechanism 28 provided under the processing vessel 1 moves up and down the substrate support pins 27 via the lifting plate 27a. The substrate support pins 27 are inserted into through-holes 2a provided in the mounting table 2, which is at the conveying position, so as to be able to project from and retract into the top surface of the mounting table 2. By the substrate support pins 27 being moved up and down, the substrate W is passed between a conveying mechanism (not shown) and the mounting table 2.

The showerhead 3 supplies a processing gas into the processing vessel 1 in a shower-like form. The showerhead 3 is composed of a metal and provided so as to face the mounting table 2, and has approximately the same diameter as that of the mounting table 2. The showerhead 3 has a body part 31 fixed to the top wall 14 of the processing vessel 1, and a shower plate 32 connected to the bottom of the body part 31. A gas diffusion space 33 is formed between the body part 31 and the shower plate 32, and the gas diffusion space 33 is provided with a gas introduction hole 36 penetrating the top wall 14 of the processing vessel 1 and the center of the body part 31. An annular projection 34 projecting downward is formed on the periphery of the shower plate 32. Gas discharge holes 35 are formed in a flat surface that is on the inner side of the annular projection 34. When the mounting table 2 is present at the processing position, the processing space (processing region) 38 is formed between the mounting table 2 and the shower plate 32, and an annular clearance (first gas exhaust path) 39 is formed between the upper surface of the cover member 22 and the annular projection 34, which have come close to each other.

The gas exhaust part 4 exhausts gas from the interior of the processing vessel 1. The gas exhaust part 4 includes a gas exhaust pipe (third gas exhaust path) 41 connected to the gas exhaust opening 13b, an Auto Pressure Controller (APC) valve 42, an opening-closing valve 43, and a vacuum pump (gas exhaust pump) 44. One end of the gas exhaust pipe 41 is connected to the gas exhaust opening 13b of the gas exhaust duct 13, and the other end thereof is connected to the aspiration port of the vacuum pump 44. The APC valve 42 and the opening-closing valve 43 are provided between the gas exhaust duct 13 and the vacuum pump 44 in order from the upstream side. The APC valve 42 adjusts the conductance of the gas exhaust path to adjust the pressure in the gas exhaust space 13a, to thereby adjust the pressure in the processing space 38. The opening-closing valve 43 switches between opening and closing of the gas exhaust pipe 41.

The gas supply part 5 supplies the processing gas into the processing vessel 1. The gas supply part 5 includes a raw material gas supply source 51a, a reaction gas supply source 52a, and purge gas supply sources 53a and 54a.

The raw material gas supply source 51a supplies a raw material gas (first processing gas) into the processing vessel 1 via a gas supply line 51b. In the following description, for example, TiCl₄ is used as the raw material gas.

The gas supply line 51b is intermediately provided with a Mass Flow Controller (MFC) 51c, a storage tank 51d, and a valve 51e in order from the upstream side. The downstream side of the valve 51e of the gas supply line 51b is connected to the gas introduction hole 36. The raw material gas supplied from the raw material gas supply source 51a is temporarily stored in the storage tank 51d before being supplied into the processing vessel 1, and is supplied into the processing vessel 1 after being pressure-raised to a predetermined pressure in the storage tank 51d. The supplying and stopping of the raw material gas from the storage tank 51d into the processing vessel 1 are performed by opening and closing of the valve 51e. By temporarily storing the raw material gas in the storage tank 51d, it is possible to supply a relatively large flow of the raw material gas stably into the processing vessel 1.

The reaction gas supply source 52a supplies a reaction gas (second processing gas) into the processing vessel 1 through a gas supply line 52b. In the following description, for example, NH₃ is used as the reaction gas.

The gas supply line 52b is intermediately provided with a mass flow controller (MFC) 52c, a storage tank 52d, and a valve 52e in order from the upstream side. The downstream side of the valve 52e of the gas supply line 52b is connected to the gas introduction hole 36. The reaction gas supplied from the reaction gas supply source 52a is temporarily stored in the storage tank 52d before being supplied into the processing vessel 1, and is supplied into the processing vessel 1 after being pressure-raised to a predetermined pressure in the storage tank 52d. The supplying and stopping of the reaction gas from the storage tank 52d into the processing vessel 1 are performed by opening and closing of the valve 52e. By temporarily storing the reaction gas in the storage tank 52d, it is possible to supply a relatively large flow of the reaction gas stably into the processing vessel 1.

The purge gas supply sources 53a and 54a supply inert gas serving as purge gas (third processing gas) into the processing vessel 1 via gas supply lines 53b and 54b. In the following description, for example, N₂ is used as the purge gas.

The gas supply lines 53b and 54b are intermediately provided with mass flow controllers (MFC) 53c and 54c, and valves 53e and 54e in order from the upstream side. The downstream sides of the valves 53e and 54e of the gas supply lines 53b and 54b are connected to the gas introduction hole 36. The purge gas supplied from the purge gas supply sources 53a and 54a is supplied into the processing vessel 1. The supplying and stopping of the purge gas from the purge gas supply sources 53a and 54a into the processing vessel 1 are performed by opening and closing of the valves 53e and 54e.

On the downstream side of the valve 53e, the gas supply line 53b merges with the downstream side of the valve 51e of the gas supply line 51b. That is, the inert gas supplied from the purge gas supply source 53a and flowing through the gas supply line 53b functions as a carrier gas for the raw material gas. The inert gas flowing through the gas supply line 53b also functions as a counter gas to prevent the reaction gas flowing through the gas supply line 52b from flowing toward the gas supply lines 51b and 53b side.

Further, on the downstream side of the valve 54e, the gas supply line 54b merges with the downstream side of the valve 52e of the gas supply line 52b. That is, the inert gas supplied from the purge gas supply source 54a and flowing through the gas supply line 54b functions as a carrier gas for the reaction gas. The inert gas flowing through the gas supply line 54b also functions as a counter gas to prevent the raw material gas flowing through the gas supply line 51b from flowing toward the gas supply lines 52b and 54b side.

The gas supply line 51b and the gas supply line 52b merge with each other on the downstream side of the merging part at which the gas supply line 51b and the gas supply line 53b merge with each other and on the downstream side of the merging part at which the gas supply line 52b and the gas supply line 54b merge with each other, to be connected to the gas introduction hole 36.

The valves 51e to 54e are, for example, opening-closing valves that are switched between a fully opened state and a fully closed state. It is preferable that the valves 51e to 54e are valves (ALD valves) that, as required in the ALD process, can be opened and closed at a high speed.

In the process, the partitioning member 17 and the mounting table 2 that is being positioned at the processing position partition the interior of the processing vessel 1 into an upper space including the processing space 38 and a lower space that is on the back side of the mounting table 2. The annular clearance 39 is formed between the upper surface of the cover member 22 of the mounting table 2 and the lower surface of the annular projection 34 of the shower plate 32. In the upper space of the processing vessel 1, the space radially inside the annular projection 34 and the annular clearance 39 becomes the processing space 38. In the upper space of the processing vessel 1, the space that is on the radially outer side of the annular projection 34 and the annular clearance 39 is the gas exhaust space 13a. The conductance of the annular clearance 39 is adjusted by the controller 9 adjusting the height of the mounting table 2 by the lifting mechanism 28 and thereby adjusting the height (gap) of the room between the upper surface of the cover member 22 of the mounting table 2 and the lower surface of the annular projection 34 of the shower plate 32.

The various gases (the raw material gas, the reaction gas, and the purge gas) supplied to the gas introduction hole 36 are diffused in the gas diffusion space 33 and supplied into the processing space 38 from the gas discharge holes 35 of the shower plate 32.

The gases in the processing space 38 reach the gas exhaust space 13a of the gas exhaust duct 13 through the annular clearance 39, and are exhausted by the vacuum pump 44 of the gas exhaust part 4 from the gas exhaust opening 13b of the gas exhaust duct 13 through the gas exhaust pipe 41. The lower space has a purge atmosphere because of a purge gas supply mechanism (not shown). Therefore, the gases in the processing space 38 do not flow into the lower space.

The showerhead 3 is provided with a gas exhaust line (second gas exhaust path) 61 leading from the processing space 38 to the gas exhaust space 13a, separately from the annular clearance 39. An inlet 61a on the upstream side of the gas exhaust line 61 is provided in the lower surface of the annular projection 34. An outlet 61b on the downstream side of the gas exhaust line 61 is provided in the lower surface of the top wall 14. The position at which the inlet 61a of the gas exhaust line 61 is provided is not limited to this, and may be provided on the processing space 38 side. When providing the processing space 38 with the inlet 61a of the gas exhaust line 61, it is preferable to provide the inlet on the radially outer side of the outer periphery (edge) of the substrate W. Thus, the processing gas can be uniformly supplied from the gas discharge holes 35 of the shower plate 32 to the substrate W, and the uniformity of the substrate processing can be improved. Further, the position at which the outlet 61b of the gas exhaust line 61 is provided is not limited to the position mentioned above, and may be provided on the gas exhaust space 13a side.

The gas exhaust line 61 is provided with a gas exhaust valve 62 for opening and closing the gas exhaust line 61. The gas exhaust valve 62 is not limited, and may be an opening/closing valve that is switched between a fully opened state and a fully closed state, may be an opening degree control valve of which the opening degree can be controlled, or may be a combination of a mass flow controller (MFC) and an opening/closing valve. Like the valves 51e to 54e, it is preferable that the gas exhaust valve 62 is an ALD valve that can be opened and closed at a high speed, as required in the ALD process.

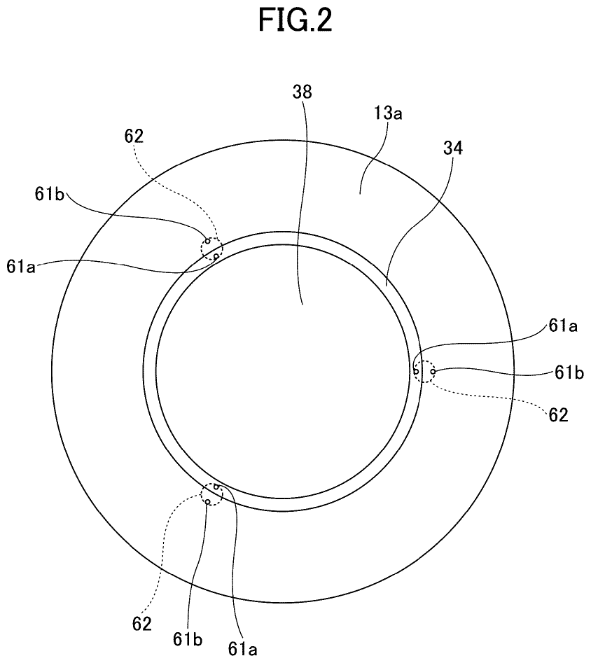

FIG. 2 is an example of a bottom view of the showerhead 3. As shown in FIG. 2, a plurality of, (three in the example of FIG. 2), gas exhaust lines 61 (inlets 61a, and outlets 61b) are provided at equal intervals in the circumferential direction.

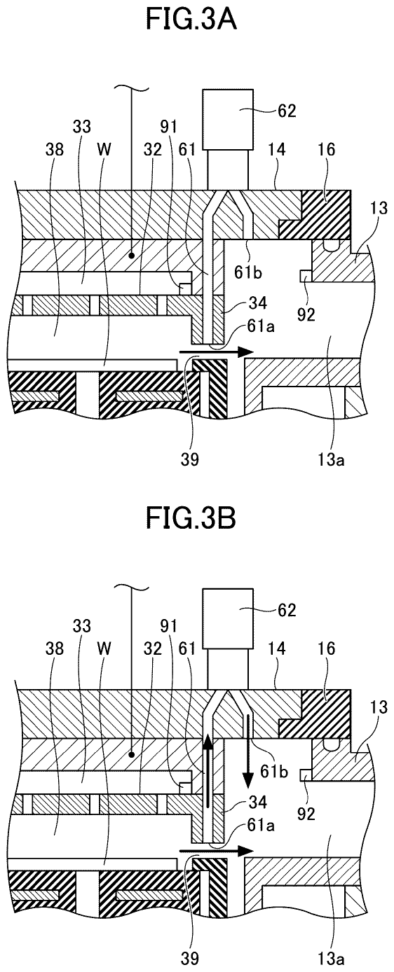

FIGS. 3A and 3B are examples of views explaining the flow of gas. In FIGS. 3A and 3B, the flow of gas is indicated by arrows.

FIG. 3A is an example of a view showing the flow of gas when the gas exhaust valve 62 is closed. When the gas exhaust valve 62 is fully closed, the gas exhaust lines 61 are closed. That is, the gas in the processing space 38 flows to the gas exhaust space 13a through the annular clearance 39. The gas flowing to the gas exhaust space 13a is exhausted outside of the apparatus through the gas exhaust pipe 41.

FIG. 3B is an example of a view showing the flow of gas when the gas exhaust valve 62 is opened. When the gas exhaust valve 62 is opened, the gas flows through the gas exhaust lines 61. That is, the gas in the processing space 38 flows to the gas exhaust space 13a through the annular clearance 39 and the gas exhaust lines 61. The gas flowing to the gas exhaust space 13a is exhausted outside of the apparatus through the gas exhaust pipe 41.

Returning to FIG. 1, the substrate processing apparatus 100 is a capacitively-coupled plasma apparatus, in which the mounting table 2 serves as a lower electrode and the showerhead 3 serves as an upper electrode. The mounting table 2 serving as the lower electrode is grounded via a capacitor (not shown).

High-frequency power (hereinafter, also referred to as “RF power”) is applied to the showerhead 3 serving as the upper electrode by the RF power supply 8. The RF power supply 8 includes a power supply line 83, a matching part 82, and a high-frequency power source 81. The high-frequency power source 81 is a power source that generates high-frequency power. The high-frequency power has a frequency suitable for generating a plasma. The frequency of the high-frequency power is, for example, within a range of 450 kHz to 100 MHz. The high-frequency power source 81 is connected to the main body 31 of the showerhead 3 via the matching part 82 and the power supply line 83. The matching part 82 includes a circuit for matching the output reactance of the high-frequency power source 81 with the reactance of a load (upper electrode). Although the RF power supply 8 has been described as applying high-frequency power to the showerhead 3 serving as the upper electrode, this is non-limiting. It may be configured to apply high-frequency power to the mounting table 2 serving as the lower electrode.

The substrate processing apparatus 100 includes pressure sensors 91 and 92. The pressure sensor 91 detects the pressure in the processing space 38 (a pressure P1 described later). Since the conductance of the shower plate 32 is sufficiently large, the pressure in the gas diffusion space 33 and the pressure in the processing space 38 are approximately the same value. Therefore, the pressure sensor 91 is allowed to be provided in the gas diffusion space 33, to be configured to estimate the pressure in the processing space 38 based on the pressure in the gas diffusion space 33. Thus, it is not necessary to provide a sensor in the processing space 38, which makes it possible to inhibit any impact from being applied to the substrate processing. The pressure sensor 92 detects the pressure (a pressure P2 described later) in the gas exhaust space 13a. The pressures detected by the pressure sensors 91 and 92 are transmitted to the controller 9.

The controller 9 is, for example, a computer and includes a Central Processing Unit (CPU), a Random Access Memory (RAM), a Read Only Memory (ROM), an auxiliary storage device, and the like. The CPU operates based on a program stored in the ROM or the auxiliary storage device to control the operation of the substrate processing apparatus 100. The controller 9 may be provided inside or outside the substrate processing apparatus 100. When the controller 9 is provided outside the substrate processing apparatus 100, the controller 9 can control the substrate processing apparatus 100 by a communication component, such as wired and wireless components and the like.

The controller 9 adjusts the processing conditions of the substrate W based on the height (gap) of the annular clearance 39 between the mounting table 2 and the showerhead 3 (gas supply mechanism), the supply conditions (gas type, flow rate, and the like) of the processing gas supplied from the showerhead 3 to the processing space 38, and the pressures in the processing vessel 1 (the pressure P1 in the processing space 38 and the pressure P2 in the gas exhaust space 13a).

### Film Forming Process of Insulating Film Using Substrate Processing Apparatus

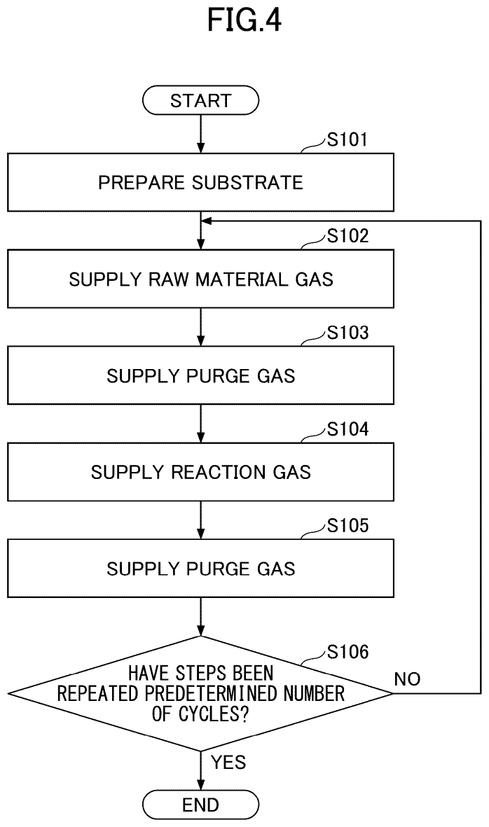

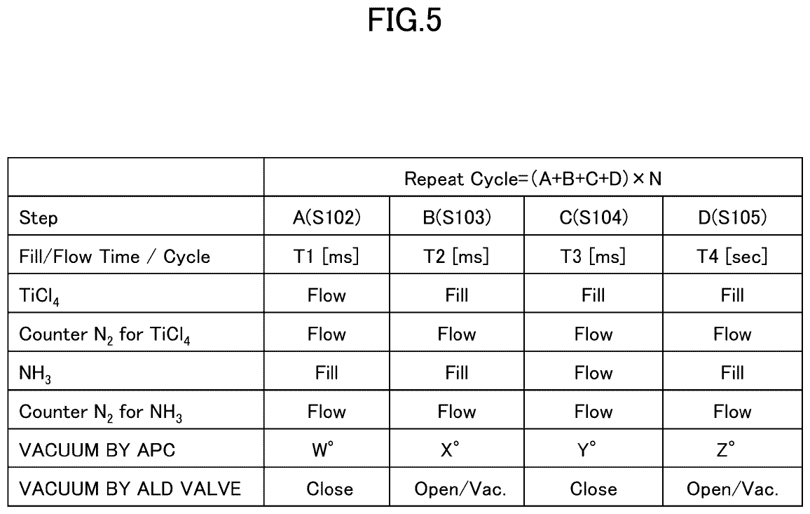

Next, an example of the operation of the substrate processing apparatus 100 will be described with reference to FIGS. 4 to 6. FIG. 4 is an example of a flowchart showing the substrate processing method. FIG. 5 is an example of a diagram showing the recipe of the substrate processing method. Here, an example case in which the substrate processing apparatus 100 forms a TiN film on the substrate W by the ALD process will be described. In FIG. 5, “Step” indicates each step (process step) of the ALD process. “Fill/Flow Time/Cycle” indicates the time duration of each step. “TiCl₄” indicates the state of the raw material gas (the raw material gas supplied from the raw material gas supply source 51a). “Counter N₂ for TiCl₄” indicates the state of the purge gas for the raw material gas (the purge gas/carrier gas/counter gas supplied from the purge gas supply source 53a). “NH₃” indicates the state of the reaction gas (the reaction gas supplied from the reaction gas supply source 52a). “Counter N₂ for NH₃” indicates the state of the purge gas for the reaction gas (the purge gas/carrier gas/counter gas supplied from the purge gas supply source 54a). “Vacuum by APC” indicates the angle of the APC valve 42. “Vacuum by ALD Valve” indicates the opened or closed state and the gas exhaust state of the gas exhaust valve 62 of the gas exhaust lines 61.

In step S101, the substrate W is prepared. First, the substrate W is loaded into the processing vessel 1 of the substrate processing apparatus 100 shown in FIG. 1. Specifically, the controller 9 controls the lifting mechanism 28 to move down the mounting table 2 to the conveying position (the position of the mounting table 2 indicated by the dash-dotted line) and opens the gate valve 12. Subsequently, the substrate W is loaded into the processing vessel 1 via the loading/unloading opening 11 by a conveying arm (not shown) and mounted on the mounting table 2 of which the temperature is adjusted to a predetermined temperature by the heater 21. After the conveying arm is retracted from the loading/unloading opening 11, the gate valve 12 is closed.

Subsequently, the controller 9 controls the lifting mechanism 28 to move up the mounting table 2 to the processing position (the position of the mounting table 2 indicated by the solid line). Thus, the annular clearance 39 is formed between the upper surface of the cover member 22 of the mounting table 2 and the lower surface of the annular projection 34 of the shower plate 32. The controller 9 also controls the angle of the APC valve 42 to depressurize the interior of the processing vessel 1 to a predetermined degree of vacuum via the gas exhaust part 4 (the vacuum pump 44). After the depressurization, the controller 9 opens the valves 53e and 54e. Thus, N₂ gas (purge gas) is supplied from the purge gas supply sources 53a and 54a into the processing space 38.

In step S101 before starting the ALD process, both the valves 51e and 52e are closed. While the valve 51e is closed, the storage tank 51d is filled with the raw material gas supplied from the raw material gas supply source 51a (Fill). While the valve 52e is closed, the storage tank 52d is filled with the reaction gas supplied from the reaction gas supply source 52a (Fill). In step S101, the gas exhaust valve 62 may be closed or opened.

Next, the controller 9 repeats the ALD process (S102 to S106) to form a desired film (TiN film) on the substrate W. The ALD process includes a step (A) of supplying the raw material gas, a step (B) of supplying the purge gas, a step (C) of supplying the reaction gas, and a step (D) of supplying the purge gas in one cycle, and repeats this cycle a predetermined number of cycles.

In step S102, the raw material gas is supplied into the processing space 38 (step A). Specifically, the controller 9 opens the valve 51e. TiCl₄ gas (raw material gas) is supplied into the processing space 38 from the raw material gas supply source 51a (TiCl₄: Flow). In addition, the controller 9 controls the angle of the APC valve 42 to a predetermined angle W [°], to depressurize the gas exhaust space 13a to a predetermined degree of vacuum via the gas exhaust part 4 (vacuum pump 44). In addition, the controller 9 closes the gas exhaust valve 62.

As the valve 52e is closed, the storage tank 52d is filled with the reaction gas supplied from the reaction gas supply source 52a (NH₃: Fill). The valve 53e has been kept opened (Counter N₂ for TiCl₄: Flow). The valve 54e has been kept opened (Counter N₂ for NH₃: Flow).

Thus, the raw material gas is adsorbed to the surface of the substrate W, and a raw material gas-adsorption layer is formed on the surface of the substrate W. Further, with the gas exhaust valve 62 closed to increase the partial pressure of the raw material gas in the processing space 38, the raw material gas adsorption efficiency is improved. When a predetermined time T1 [ms] has elapsed, the controller 9 closes the valve 51e, and the controller 9 proceeds to the next step S103.

In step S103, the purge gas is supplied into the processing space 38 (step B). Specifically, the controller 9 keeps the valves 53e and 54e opened (Counter N₂ for TiCl₄: Flow) (Counter N₂ for NH₃: Flow). N₂ gas (purge gas) is supplied into the processing space 38 from the purge gas supply sources 53a and 54a. The controller 9 controls the angle of the APC valve 42 to a predetermined angle X [°], to depressurize the gas exhaust space 13a to a predetermined degree of vacuum via the gas exhaust part 4 (vacuum pump 44). The controller 9 opens the gas exhaust valve 62.

As the valve 51e is closed, the storage tank 51d is filled with the raw material gas supplied from the raw material gas supply source 51a (TiCl₄: Fill). Moreover, as the valve 52e is closed, the storage tank 52d is filled with the reaction gas supplied from the reaction gas supply source 52a (NH₃: Fill).

As a result, excess raw material gas and the like in the processing space 38 are purged by the purge gas. When a predetermined time T2 [ms] has elapsed, the controller 9 proceeds to the next step S104.

In step S104, the reaction gas is supplied into the processing space 38 (step C). Specifically, the controller 9 opens the valve 52e. The NH₃ gas (reaction gas) is supplied from the reaction gas supply source 52a into the processing space 38 (NH₃: Flow). The controller 9 controls the angle of the APC valve 42 to a predetermined angle Y [°], to depressurize the gas exhaust space 13a to a predetermined degree of vacuum via the gas exhaust part 4 (vacuum pump 44). The controller 9 closes the gas exhaust valve 62.

As the valve 51e is closed, the storage tank 51d is filled with the raw material gas supplied from the raw material gas supply source 51a (TiCl₄: Fill). The valve 53e has been kept opened (Counter N₂ for TiCl₄: Flow). The valve 54e has been kept opened (Counter N₂ for NH₃: Flow).

Thus, the raw material gas that has adsorbed to the surface of the substrate W reacts with the reaction gas to form one layer of TiN. With the gas exhaust valve 62 closed to increase the partial pressure of the reaction gas in the processing space 38, the reaction efficiency of the reaction gas is improved. When a predetermined time T3 [ms] has elapsed, the controller 9 closes the valve 52e, and the controller 9 proceeds to the next step S105.

In step S105, the purge gas is supplied into the processing space 38 (step D). Specifically, the controller 9 keeps the valves 53e and 54e opened (Counter N₂ for TiCl₄: Flow) (Counter N₂ for NH₃: Flow). The N₂ gas (purge gas) is supplied into the processing space 38 from the purge gas supply sources 53a and 54a. The controller 9 controls the angle of the APC valve 42 to a predetermined angle Z [°], to depressurize the gas exhaust space 13a to a predetermined degree of vacuum via the gas exhaust part 4 (vacuum pump 44). The controller 9 opens the gas exhaust valve 62.

As the valve 51e is closed, the storage tank 51d is filled with the raw material gas supplied from the raw material gas supply source 51a (TiCl₄: Fill). As the valve 52e is closed, the storage tank 52d is filled with the reaction gas supplied from the reaction gas supply source 52a (NH₃: Fill).

As a result, excess reaction gas and the like in the processing space 38 are purged by the purge gas. When a predetermined time T4 [ms] has elapsed, the controller 9 proceeds to the next step S106.

In step S106, the controller 9 determines whether or not the number of cycles has reached the predetermined repeating number of times, by regarding the process from step S102 to step S105 as one cycle. When the predetermined repeating number of times has not been reached (S106: NO), the controller 9 returns to step S102 and repeats the cycle from step S102 to step S105. When the predetermined repeating number of times has been reached (S106: YES), the controller 9 ends the process shown in FIG. 4.

Thereafter, the controller 9 controls the lifting mechanism 28 to move down the mounting table 2 to the conveying position (the position of the mounting table 2 indicated by the dash-dotted line) and opens the gate valve 12. Subsequently, the substrate W is unloaded from the processing vessel 1 via the loading/unloading opening 11 by the conveying arm (not shown). After the conveying arm is retreated from the loading/unloading opening 11, the gate valve 12 is closed.

Here, the mass flow rate of the gas controlled by the mass flow controllers (51c to 54c) is defined as the mass flow rate Q1. The mass flow rate of the gas supplied into the processing space 38 when the valves (51e to 54e) are opened is defined as the mass flow rate Q2. The mass flow rate of the gas flowing through the annular clearance (first gas exhaust path) 39 is defined as the mass flow rate Qg. The mass flow rate of the gas flowing through the gas exhaust lines (second gas exhaust path) 61 is defined as the mass flow rate Qv. The conductance of the annular clearance (first gas exhaust path) 39 is defined as the conductance Cg, and the conductance of the gas exhaust lines (second gas exhaust path) 61 is defined as the conductance Cv. In this case, there are relationships represented by the following expressions (1) and (2).

$$Qv ∝ Cv / ( Cv + Cg ) \qquad ( 1 )$$

$$Q 2 = Qv + Qg \qquad ( 2 )$$

Here, if Cv>>Cg, most of gas exhausted from the processing space 38 into the gas exhaust space 13a flows through the gas exhaust lines 61. In other words, in a state in which the gas exhaust valve 62 is opened, the mass flow rate Qv of the gas flowing through the gas exhaust lines (second gas exhaust path) 61 is greater than the mass flow rate Qg of the gas flowing through the annular clearance (first gas exhaust path) 39 (Qv>Qg). In this case, there is a relationship represented by the following expression (3).

$$Q 2 \approx Qv \qquad ( 3 )$$

The pressure in the processing space 38 is defined as the pressure P1. The pressure in the gas exhaust space 13a is defined as the pressure P2.

When the height (gap) between the upper surface of the cover member 22 of the mounting table 2 and the lower surface of the annular projection 34 of the shower plate 32 is sufficiently large, the pressure P1 in the processing space 38 and the pressure P2 in the gas exhaust space 13a are almost equal (P1≈P2). In this case, it is possible to control the pressure P1 in the processing space 38 by controlling the APC valve 42 so as to control the pressure P2 in the gas exhaust space 13a.

When the height (gap) between the upper surface of the cover member 22 of the mounting table 2 and the lower surface of the annular projection 34 of the shower plate 32 becomes small, a pressure difference occurs between the pressure P1 in the processing space 38 and the pressure P2 in the gas exhaust space 13a. The mass flow rate Qg is proportional to the pressure difference (P1−P2). In this case as well, it is possible to control the gas exhaust mass flow rate Qg by controlling the APC valve 42 so as to control the pressure P2 in the gas exhaust space 13a.

Then, when the height (gap) between the upper surface of the cover member 22 of the mounting table 2 and the lower surface of the annular projection 34 of the shower plate 32 becomes smaller to be equal to or less than a predetermined height, the pressure P1 on the upstream side becomes twice or more the pressure P2 on the downstream side (P1≥2P2), to reach the critical pressure ratio. When the critical pressure ratio is reached, the gas exhaust mass flow rate Qg becomes dependent on the pressure P1 on the upstream side and can no longer be controlled based on the pressure P2 on the downstream side.

That is, by reducing the gap of the annular clearance 39, it is possible to improve the raw material gas adsorption efficiency in step S102 and to improve the reaction efficiency in step S104. On the other hand, when gas exhaustion is only via the annular clearance 39 in the purge steps (S103 and S105), it is difficult to exhaust the gas in the processing space 38 in a short time.

In this regard, in the substrate processing apparatus 100 shown in FIG. 1, the gas exhaust valve 62 is opened in the purge steps (S103 and S105). Thus, the gas in the processing space 38 can be exhausted in a short time. In addition, the gas exhaust mass flow rate (Qg+Qv) is controlled by controlling the APC valve 42 so as to control the pressure P2 in the gas exhaust space 13a while inhibiting the critical pressure ratio from being reached. That is, it is possible to control the mass flow rate Q2 (=Qg+Qv).

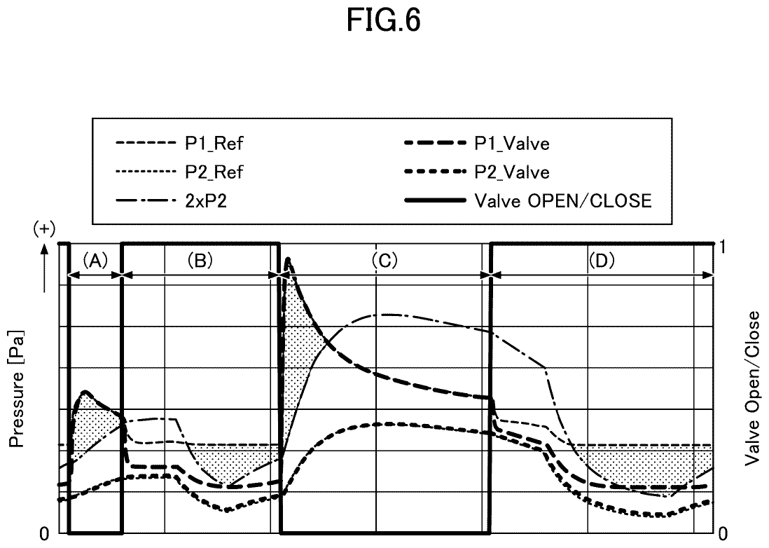

FIG. 6 is a graph showing an example of pressure change. The horizontal axis indicates time. The vertical axis indicates each pressure (left vertical axis) and opening/closing of the gas exhaust valve 62 (right vertical axis). As the opening and closing of the gas exhaust valve 62, a fully closed state is indicated by 0 and a fully opened state is indicated by 1. Here, cases where the ALD process is performed with the gas exhaust valve 62 closed (Ref) and cases where the ALD process involving opening and closing of the gas exhaust valve 62 is performed (Valve) will be described.

(P1_Ref) indicates the pressure P1 in the processing space 38 when the ALD process is performed with the gas exhaust valve 62 closed. (P2_Ref) indicates the pressure P2 in the gas exhaust space 13a when the ALD process is performed with the gas exhaust valve 62 closed. (2×P2) is a value that is twice (P2_Ref) and is a threshold value for whether or not the critical pressure ratio is reached.

(P1_Valve) indicates the pressure P1 in the processing space 38 when the ALD process involving opening and closing of the gas exhaust valve 62 is performed. (P2_Valve) indicates the pressure P2 in the gas exhaust space 13a when the ALD process involving opening and closing of the gas exhaust valve 62 is performed. (Valve OPEN/CLOSE) is a graph showing the opening and closing of the gas exhaust valve 62.

The angle control of the APC valve 42 when the ALD process is performed with the gas exhaust valve 62 closed (Ref) and that when the ALD process involving opening and closing of the gas exhaust valve 62 is performed (Valve) are performed in the same manner. Therefore, the pressures (P2_Ref) and (P2_Valve) conform to each other.

In the step (A) of supplying the raw material gas and in the step (C) of supplying the reaction gas, the gas exhaust valve 62 is closed both when the ALD process is performed with the gas exhaust valve 62 closed (Ref) and when the ALD process involving opening and closing of the gas exhaust valve 62 is performed (Valve). Therefore, the pressures (P1_Ref) and (P1_Valve) match. In the regions shaded with dots, the critical pressure ratio is reached. That is, in steps S102 and S104, there are time regions in which the pressure P1 in the processing space 38 cannot be controlled by the APC valve 42.

If the ALD process is performed with the gas exhaust valve 62 closed (Ref) in the step (B) of supplying the purge gas and in the step (D) of supplying the purge gas, the pressure P1 (P1_Ref) does not sufficiently lower and the pressure P2 (P2_Ref) reaches the critical pressure ratio (see the regions shaded with dots). That is, even lowering the pressure P2 (P2_Valve) cannot avoid the purge efficiency being limited.

On the other hand, in a case where the ALD process involving opening and closing of the gas exhaust valve 62 is performed (Valve) in the step (B) of supplying the purge gas and in the step (D) of supplying the purge gas, it is possible to lower the degree of vacuum to be reached by the pressure P1 (P1_Valve). Therefore, it is possible to inhibit the critical pressure ratio from being reached, and to improve the purge efficiency by lowering the pressure P2 (P2_Valve).

In the example shown in FIGS. 4 to 6, the gas exhaust valve 62 has been explained as being closed in the step (A) of supplying the raw material gas and in the step (C) of supplying the reaction gas, and the gas exhaust valve 62 has been explained as being opened in the step (B) of supplying the purge gas and in the step (D) of supplying the purge gas. However, this is non-limiting.

For example, when the pressure P1 in the processing space (processing region) 38 is twice or more the pressure P2 in the gas exhaust space (gas exhaust region) 13a (P1≥2P2), the controller 9 opens the gas exhaust valve 62 to adjust the mass flow rate of the gas exhaust lines (second gas exhaust path) 61. Here, the opening degree of the gas exhaust valve 62 may be adjusted. Thus, by controlling the APC valve 42 to control the pressure P2 in the gas exhaust space 13a while inhibiting the critical pressure ratio from being reached in this way, it is possible to control the gas exhaust mass flow rate Qg and to control the pressure P1 in the processing space 38.

For example, the controller 9 opens the gas exhaust valve 62 and adjusts the mass flow rate of the gas exhaust lines (second gas exhaust path) 61 based on the pressure P1 in the processing space (processing region) 38 detected by the pressure sensor 91 and the pressure P2 in the gas exhaust space (gas exhaust region) 13a detected by the pressure sensor 92. Here, the opening degree of the gas exhaust valve 62 may be adjusted. Thus, by controlling the APC valve 42 to control the pressure P2 in the gas exhaust space 13a while inhibiting the critical pressure ratio from being reached in this way, it is possible to control the gas exhaust mass flow rate Qg and to control the pressure P1 in the processing space 38.

The substrate processing method by the substrate processing apparatus 100 has been described above. However, the present disclosure is not limited to the above-described embodiment, and various modifications and improvements are applicable within the scope of the spirit of the present disclosure described in the claims.

According to one aspect, the present disclosure can provide a substrate processing apparatus and a substrate processing method for controlling the state of a processing gas in a processing region.

What is claimed is:

1. A substrate processing apparatus, comprising:
a processing chamber;
a mounting table that is situated in the processing chamber and on which a substrate is mounted;
a gas supply mechanism situated so as to face the mounting table and configured to supply a processing gas to the substrate;
a processing region formed between the mounting table and the gas supply mechanism;
a gas exhaust region via which a gas is exhausted by a gas exhaust part;
a first gas exhaust path that is formed in a gap between the mounting table and the gas supply mechanism and through which the processing gas flows from the processing region to the gas exhaust region;
a second gas exhaust path provided in the gas supply mechanism and connecting the processing region to the gas exhaust region such that the processing gas can flow from the processing region to the gas exhaust region;
a third gas exhaust path through which the processing gas is exhausted from the gas exhaust region; and
a controller,
wherein the controller is configured to adjust a processing condition of the substrate based on the gap between the mounting table and the gas supply mechanism, a supply condition of the processing gas supplied from the gas supply mechanism, and a pressure in the processing chamber.

2. The substrate processing apparatus according to claim 1, further comprising:
a lifting mechanism configured to move the mounting table up and down to adjust the gap between the mounting table and the gas supply mechanism.

3. The substrate processing apparatus according to claim 1, further comprising:
a gas exhaust valve provided on the second gas exhaust path,
wherein a mass flow rate adjustment of the second gas exhaust path is performed when a pressure in the processing region is twice or more a pressure in the gas exhaust region.

4. The substrate processing apparatus according to claim 3,
wherein when the gas exhaust valve is opened, a mass flow rate of the processing gas flowing into the second gas exhaust path is greater than a mass flow rate of the processing gas flowing into the first gas exhaust path.

5. The substrate processing apparatus according to claim 3,
wherein the controller performs the mass flow rate adjustment of the second gas exhaust path based on a pressure detected by a first pressure sensor configured to detect the pressure in the processing region and a pressure detected by a second pressure sensor configured to detect the pressure in the gas exhaust region.

6. The substrate processing apparatus according to claim 1,
wherein a pressure in the gas exhaust region is controlled by a pressure controller provided on the third gas exhaust path.

7. The substrate processing apparatus according to claim 1, further comprising:
a gas exhaust valve provided on the second gas exhaust path,
wherein the controller repeats a cycle, which includes as one cycle:
supplying of a first processing gas into the processing region;
first supplying of a purge gas into the processing region to purge the first processing gas in the processing region;
supplying of a second processing gas into the processing region; and
second supplying of a purge gas into the processing region to purge the second processing gas in the processing region,
wherein the gas exhaust valve is opened in the first supplying of the purge gas and in the second supplying of the purge gas, and
wherein the gas exhaust valve is closed in the supplying of the first processing gas and in the supplying of the second processing gas.

8. A substrate processing method of a substrate processing apparatus including: a processing chamber; a mounting table that is situated in the processing chamber and on which a substrate is mounted; a gas supply mechanism situated so as to face the mounting table and configured to supply a processing gas to the substrate; a processing region formed between the mounting table and the gas supply mechanism; a gas exhaust region via which a gas is exhausted by a gas exhaust part; a first gas exhaust path that is formed in a gap between the mounting table and the gas supply mechanism and through which the processing gas flows from the processing region to the gas exhaust region; a second gas exhaust path provided in the gas supply mechanism and connecting the processing region to the gas exhaust region such that the processing gas can flow from the processing region to the gas exhaust region; and a third gas exhaust path through which the processing gas is exhausted from the gas exhaust region, the substrate processing apparatus being configured to perform processing on the substrate,
the substrate processing method comprising:
adjusting a processing condition of the substrate based on the gap between the mounting table and the gas supply mechanism, a supply condition of the processing gas supplied from the gas supply mechanism, and a pressure in the processing chamber.

9. The substrate processing method according to claim 8, further comprising:
a lifting mechanism configured to move the mounting table up and down to adjust the gap between the mounting table and the gas supply mechanism.

10. The substrate processing method according to claim 8, further comprising:
a gas exhaust valve provided on the second gas exhaust path,
wherein a mass flow rate adjustment of the second gas exhaust path is performed when a pressure in the processing region is twice or more a pressure in the gas exhaust region.

11. The substrate processing method according to claim 10,
wherein when the gas exhaust valve is opened, a mass flow rate of the processing gas flowing into the second gas exhaust path is greater than a mass flow rate of the processing gas flowing into the first gas exhaust path.

12. The substrate processing method according to claim 10,
wherein the mass flow rate adjustment of the second gas exhaust path is performed based on a pressure detected by a first pressure sensor configured to detect the pressure in the processing region and a pressure detected by a second pressure sensor configured to detect the pressure in the gas exhaust region.

13. The substrate processing method according to claim 8,
wherein a pressure in the gas exhaust region is controlled by a pressure controller provided in the third gas exhaust path.

14. The substrate processing method according to claim 8, further comprising:
a gas exhaust valve provided on the second gas exhaust path,
wherein the substrate processing method comprises repeating a cycle, which includes as one cycle;
supplying of a first processing gas into the processing region;
first supplying of a purge gas into the processing region to purge the first processing gas in the processing region;
supplying of a second processing gas into the processing region; and
second supplying of a purge gas into the processing region to purge the second processing gas in the processing region,
wherein the gas exhaust valve is opened in the first supplying of the purge gas and in the second supplying of the purge gas, and
wherein the gas exhaust valve is closed in the supplying of the first processing gas and in the supplying of the second processing gas.
